(19) United States
(12) Patent Application Publication
(10) Pub. No.: US 2012/0180953 A1
(43) Pub. Date: Jul. 19, 2012

(54) PLASMA PROCESSING APPARATUS AND WAVE RETARDATION PLATE USED THEREIN

(75) Inventors: Shigenori Ozaki, Amagasaki City (JP); Ryusaku Ota, Nirasaki City (JP); Hikaru Adachi, Nirasaki City (JP); Makoto Ishitsubo, Nirasaki City (JP)

(73) Assignee: Tokyo Electron Limited, Tokyo (JP)

(21) Appl. No.: 13/498,339

(22) PCT Filed: Sep. 29, 2010
(86) PCT No.: PCT/JP10/66946

§ 371 Date: Mar. 27, 2012

(30) Foreign Application Priority Data
Sep. 30, 2009 (JP) 2009-225984

(51) Int. Cl. B05C 9/00; H01Q 15/08; C23C 16/50

(52) U.S. Cl. 156/345.1; 118/723 R; 343/911 R

(57) ABSTRACT

A plasma processing apparatus includes a planar antenna member, which introduces electromagnetic waves generated by means of an electromagnetic wave generator into a processing chamber; a waveguide which supplies the electromagnetic waves to the planar antenna member; and a wave retardation plate, which is provided on the planar antenna member, and changes the wavelength of the electromagnetic waves supplied from the waveguide; a cover member which covers the wave retardation plate and the planar antenna member from above. The wave retardation plate is configured using a dielectric material, and the permittivity of the region between the planar antenna member and the cover member is not uniform on the plane parallel to the upper surface of the planar antenna member.

### FIELD OF THE INVENTION

The present invention relates to a plasma processing apparatus for performing plasma processing on an object to be processed by generating a plasma by transmitting an electromagnetic wave of a predetermined frequency into a processing chamber, and a wave retardation plate used therein.

### BACKGROUND OF THE INVENTION

As for a plasma processing apparatus for performing plasma processing, e.g., oxidation, nitriding, etching, CVD (Chemical Vapor Deposition) or the like, on an object to be processed such as a semiconductor or the like, there is known a slot antenna type plasma processing apparatus for generating a plasma by introducing a microwave into a processing chamber through a planar antenna having a plurality of slots. In this microwave plasma processing apparatus, a high-density surface wave plasma can be generated in the processing chamber.

In view of developing next generation devices, in order to improve productivity while dealing with miniaturization or processing of, e.g., three-dimensional devices, even when a large-sized substrate is processed, the in-plane processing uniformity of the substrate needs to be ensured even when a large-sized substrate is processed. To do so, it is required to improve controllability of distribution of a plasma generated in a processing chamber that is scaled up in accordance with the scaling up of the substrate.

In the slot antenna type plasma processing apparatus, the distribution of the plasma generated in the processing chamber is controlled depending on the shapes or arrangements of the slots, the shape of the processing chamber or the microwave transmitting plate, or the like. For example, in order to change the distribution of the plasma depending on types of processing, a planar antenna having another slot shape and arrangement should be used. However, the replacement of the planar antenna is a large-scale operation which requires time and effort. Further, when the plasma distribution becomes asymmetric and non-uniform in the processing chamber due to various factors such as manufacturing tolerances of the planar antenna, the processing chamber or the like, assembly errors, differences between devices having the same specifications or the like, the extensive modification of the apparatus such as replacement of the planar antenna or the like is required because there is not provided a method for simply correcting the non-uniformity of the plasma distribution.

### SUMMARY OF THE INVENTION

In view of the above, the present invention provides a plasma processing apparatus capable of controlling distribution of a plasma generated in a processing chamber with a simple structure.

In accordance with one aspect of the present invention, there is provided a plasma processing apparatus for performing plasma processing on an object to be processed, including: a vacuum-evacuable processing chamber for accommodating therein an object to be processed; a planar antenna member for introducing electromagnetic waves generated by an electromagnetic wave generator into the processing chamber; a waveguide for supplying the electromagnetic waves to the planar antenna member; a wave retardation plate, provided on the planar antenna member in an overlapped manner, for changing the wavelength of the electromagnetic waves supplied from the waveguide; and a cover member covering the wave retardation plate and the planar antenna member from above. The wave retardation plate is made of a dielectric material, and a permittivity of a region between the planar antenna member and the cover member is non-uniform on a plane parallel to an upper surface of the planar antenna member.

In accordance with another aspect of the present invention, there is provided a wave retardation plate, provided on a planar antenna member of a plasma processing apparatus in an overlapped manner, for changing a wavelength of an electromagnetic wave supplied from a waveguide, wherein the wave retardation plate is made of a dielectric material, and a permittivity of a region between the planar antenna member and a cover member covering the planar antenna member from above is non-uniform on a plane parallel to an upper surface of the planar antenna member.

### EFFECTS OF THE INVENTION

In accordance with the present invention, the wave retardation plate made of a dielectric material is configured such that the permittivity of the region between the planar antenna member and the cover member is variable on a plane parallel to the upper surface of the planar antenna member. Thus, the plasma distribution in the processing chamber can be controlled by controlling a wavelength of an electromagnetic wave without exchanging the planar antenna member. Accordingly, desired distribution of the plasma can be stably maintained in the processing chamber. In addition, even when the processing chamber is scaled up in accordance with the scaling up of the substrate, the distribution of the plasma generated in the processing chamber can be simply controlled by changing the structure of the wave retardation plate.

### BRIEF DESCRIPTION OF THE DRAWINGS

FIG. 1 is a schematic cross sectional view showing a configuration example of a plasma processing apparatus in accordance with a first embodiment of the present invention.

FIG. 2 is a top view of a planar antenna plate.

FIG. 3 is an exterior perspective view showing arrangement of a wave retardation plate in accordance with a first embodiment of the present invention.

FIG. 4 is a top view of the planar antenna plate of FIG. 3.

FIG. 5 is a cross sectional view of principal parts of the plasma processing apparatus and shows the attachment state of the wave retardation plate.

FIG. 6 is a top view showing a modification of the wave retardation plate of the first embodiment.

FIG. 7 is a top view showing another modification of the wave retardation plate of the first embodiment.

FIG. 8 is a top view showing still another modification of the wave retardation plate of the first embodiment.

FIG. 9 is a top view showing still another modification of the wave retardation plate of the first embodiment.

FIG. 10 is a block diagram showing a schematic configuration of a control system of the plasma processing apparatus shown in FIG. 1.

FIG. 11 is a top view showing a wave retardation plate in accordance with a second embodiment of the present invention.

FIG. 12 is a top view showing a modification of the wave retardation plate of the second embodiment.

FIG. 13 is a top view showing another modification of the wave retardation plate of the second embodiment.

FIG. 14 is an exterior perspective view showing arrangement of a wave retardation plate in accordance with a third embodiment of the present invention.

FIG. 15 is a cross sectional view of principal parts of the plasma processing apparatus and shows the attachment state of the wave retardation plate.

FIG. 16 is a cross sectional view of principal parts of the plasma processing apparatus and shows a modification of the wave retardation plate of the third embodiment.

FIG. 17 is a cross sectional view of principal parts of the plasma processing apparatus and shows the attachment state of the wave retardation plate of the fourth embodiment.

FIG. 18 is a cross sectional view of principal parts of the plasma processing apparatus and shows another attachment state of the wave retardation plate of the fourth embodiment.

FIG. 19 is a top view of a wave retardation plate in accordance with a fifth embodiment of the present invention.

FIG. 20 is a top view showing a modification of the wave retardation plate of the fifth embodiment.

FIG. 21 shows electric field intensity distribution below a transmitting plate which is obtained by a simulation test.

FIG. 22 shows electric field intensity distribution below a transmitting plate which is obtained by a simulation test.

### DETAILED DESCRIPTION OF THE EMBODIMENTS

### First Embodiment

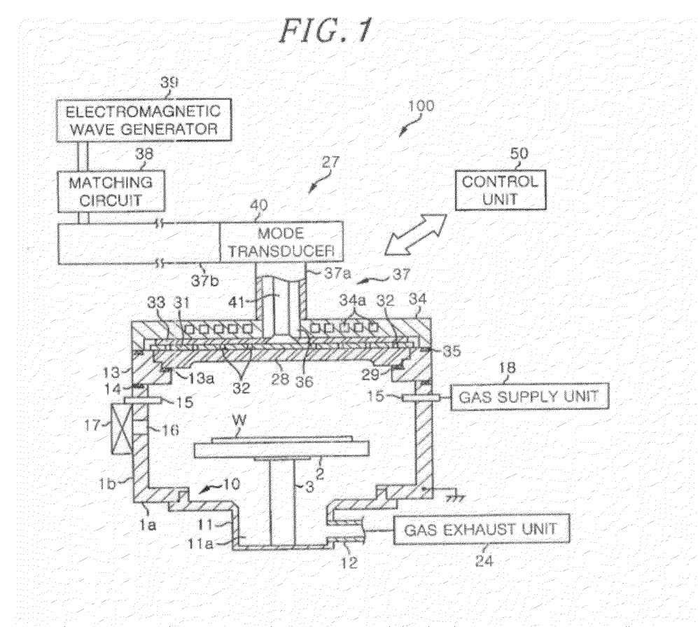

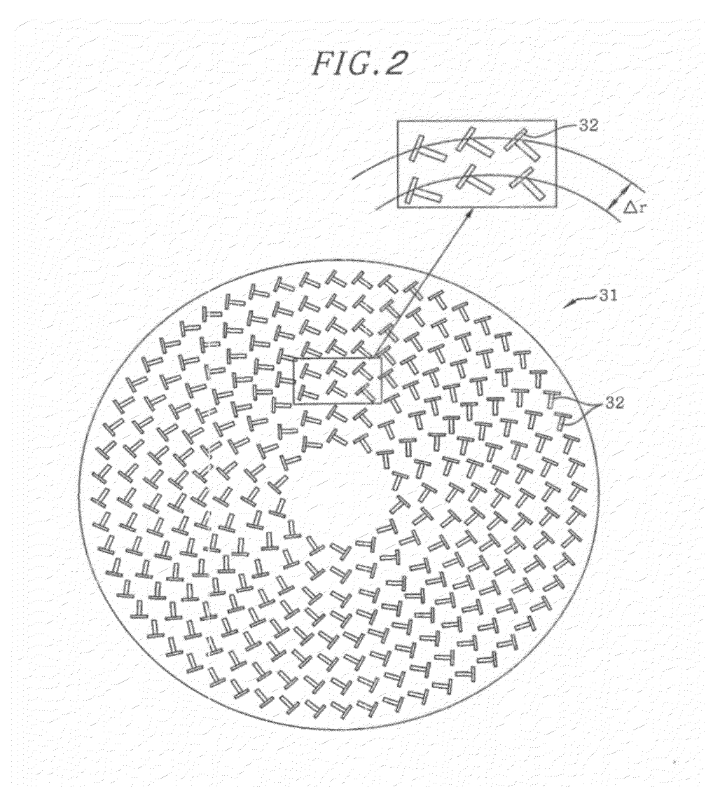

Hereinafter, embodiments of the present invention will be described in detail with reference to the accompanying drawings. FIG. 1 is a cross sectional view schematically showing a configuration example of a plasma processing apparatus 100 in accordance with a first embodiment of the present invention. FIG. 2 is a top view showing a planar antenna used in the plasma processing apparatus 100 shown in FIG. 1. The plasma processing apparatus 100 is configured as a plasma processing apparatus capable of generating a plasma of a high density and a low electron temperature by introducing a microwave into the processing chamber by using a planar antenna having a plurality of slots, particularly an RLSA (Radial Line Slot Antenna). The plasma processing apparatus 100 can perform a process using a plasma having a density of about 10⁹/cm³ to 10¹³/cm³ and a low electron temperature of about 2 eV or less. Accordingly, the plasma processing apparatus 100 can be preferably used in a manufacturing process of various semiconductor devices.

The plasma processing apparatus 100 mainly includes: an airtight processing chamber 1; a gas supply unit 18 for supplying a gas into the processing chamber 1; a gas inlet 15 connected to the gas supply unit 18; a gas exhaust unit for depressurizing and exhausting the interior of the processing chamber 1; a microwave introducing mechanism 27, provided at an upper portion of the processing chamber 1, for introducing a microwave into the processing chamber 1; and a control unit 50 as a control device for controlling each component of the plasma processing apparatus 100. The gas supply unit 18, the gas exhaust unit 24, and the microwave introducing mechanism 27 form a plasma generation unit for generating a plasma of a processing gas in the processing chamber 1. Further, the gas supply unit 18 may not be included in the components of the plasma processing apparatus 100. In that case, an external gas supply unit may be connected to the gas inlet 15.

The processing chamber 1 is formed by a substantially cylindrical container which is grounded. Moreover, the processing chamber 1 may be formed by a square column shaped container. The processing chamber 1 has a bottom wall la and a sidewall 1b made of aluminum or the like.

The mounting table 2 for horizontally supporting a silicon wafer W (hereinafter, simply referred to as a “wafer”) as an object to be processed is provided in the processing chamber 1. The mounting table 2 is made of a material having high thermal conductivity, e.g., ceramic such as AlN or the like. The mounting table 2 is supported by a cylindrical supporting member 3 extending upwardly from a center of a bottom portion of the gas exhaust chamber 11. The supporting member 3 is made of, e.g., ceramic such as AlN or the like.

Moreover, the mounting table 2 is provided with a heating mechanism or a cooling mechanism, so that a temperature of the wafer W can be controlled, e.g., in a range from a room temperature to about 900° C.

Further, wafer support pins (not shown) for supporting and vertically moving the wafer W are provided at the mounting table 2. Each of the wafer support pins can be protruded from and retracted into the surface of the mounting table 2.

A circular gas exhaust port 10 is formed at a substantially central portion of the bottom wall 1a of the chamber 1. A gas exhaust chamber 11 extends downward from the bottom wall 1a and communicates with the gas exhaust port 10. A gas exhaust line 12 is connected to the gas exhaust chamber 11, and the gas exhaust chamber 11 is connected to a gas exhaust unit 24 via the gas exhaust line 12.

An annular plate 13 having an annular inner periphery and serving as a lid for opening and closing the processing chamber 1 is provided at an upper portion of the processing chamber 1. An inner peripheral portion of the plate 13 protrudes inwardly (toward the inner space of the processing chamber) and thus forms an annular support portion 13a for supporting a transmitting plate 28. The plate 13 and the processing chamber 1 are airtightly sealed via a sealing member 14.

An annular gas inlet 15 is disposed at the sidewall 1b of the processing chamber 1. The gas inlet 15 is connected to the gas supply unit 18 for supplying an oxygen-containing gas or a gas for plasma excitation via a line. Further, the gas inlet 15 may be formed in a nozzle shape protruding toward the inside of the processing chamber 1 or a shower shape having a plurality of gas holes.

The gas supply unit 18 includes gas supply sources (not shown) for supplying gases such as a rare gas for plasma generation, such as Ar, Kr, Xe or He; a processing gas, such as an oxidizing gas for an oxidation process, e.g., 02 or the like, or a nitriding gas for a nitriding process. Besides, there may be provided supply sources for supplying gases such as an etching gas for an etching process, e.g., Cl₂, BCl₃, CF₄ or the like; a film forming gas for a CVD process; a purge gas for replacement of the atmosphere in the processing chamber, such as N₂, Ar or the like; a cleaning gas for cleaning the interior of the processing chamber 1, such as ClF₃, NF₃ or the like. Each gas supply source is provided with a mass flow controller and an opening/closing valve (both not shown) so that the switching of gases to be supplied or control of gas flow rates can be performed.

Provided on the sidewall 1b of the processing chamber 1 is a loading/unloading port 16 for loading and unloading the wafer W between the plasma processing apparatus 100 and a transfer chamber (not shown) adjacent thereto, and a gate valve 17 for opening and closing the loading/unloading port 16.

The gas exhaust unit 24 includes a high speed vacuum pump, e.g., a turbo molecular pump or the like. As described above, the gas exhaust unit 24 is connected to the gas exhaust chamber 11 of the processing chamber 1 via the gas exhaust line 12. By operating the gas exhaust unit 24, the gas in the processing chamber 1 uniformly flows in the space 11a of the gas exhaust chamber 11, and is discharged from the space 11a to the outside via the gas exhaust line 12. Accordingly, the processing chamber 1 can be depressurized to, e.g., about 0.133 Pa, at a high speed.

Hereinafter, the configuration of the microwave introducing mechanism 27 will be described. The microwave introducing mechanism 27 mainly includes a transmitting plate 28, a planar antenna 31, a wave retardation plate 33, a cover member 34, a waveguide 37, and a matching circuit 38, and an electromagnetic wave generator 39.

The transmitting plate 28 for transmitting a microwave is provided on the support portion 13a protruded from the inner peripheral portion of the plate 13. The transmitting plate 28 is made of a dielectric material, e.g., quartz or ceramic such as Al₂O_{3,} AlN or the like. The transmitting plate 28 and the support portion 13a are airtightly sealed via a sealing member 29. Hence, the upper opening of the processing chamber 1 is closed by the transmitting plate 28 1 via the plate 13, and the airtightness in the processing chamber 1 is maintained.

The planar antenna 31 is provided above the transmitting plate 28 so as to face the mounting table 2. The planar antenna 31 is formed in a disc shape. However, the planar antenna 31 is not limited to the disc shape but may be of, e.g., a quadrilateral plate shape. The planar antenna 31 is engaged to the top end of the plate 13.

The planar antenna 31 is made of, e.g., a cupper plate or an aluminum plate whose surface is coated with gold or silver. The planar antenna 31 has a plurality of slot-shaped microwave irradiation holes 32 for radiating a microwave. The microwave irradiation holes 32 are formed through the planar antenna 31 in a predetermined pattern.

As illustrated in FIG. 2, each of the microwave irradiation holes 32 has a narrow and long rectangular shape (slot shape). Further, a pair of adjacent microwave irradiation holes 32 is typically arranged in a “T” shape. Furthermore, such pairs of the microwave irradiation holes arranged in a predetermined shape (e.g., T-shape) are arranged along concentric circular lines as a whole.

A length of each of the microwave irradiation holes 32 or an arrangement interval between the microwave irradiation holes 32 is determined by a wavelength (Ag) of a microwave. For example, the microwave irradiation holes 32 are arranged so as to be spaced apart from each other at an interval of λg/4 to λg. Referring to FIG. 2, a distance between the adjacent microwave irradiation holes 32 arranged concentrically is indicated by Δr. The microwave irradiation holes 32 may have a circular shape, an arc shape or the like. Moreover, the arrangement pattern of the microwave radiation holes 32 is not limited to the concentric circular pattern, and they may be arranged in, e.g., a spiral pattern, a radial pattern or the like.

The wave retardation plate 33 is provided on an upper surface of the planar antenna 31. The wave retardation plate 33 is made of a material having a permittivity greater than that of vacuum. For example, the wafer retardation plate 33 is made of quartz, alumina, aluminum nitride or the like. The wave retardation member 33 has a function of controlling the microwave electric field distribution on the upper surface of the planar antenna plate by shortening the wavelength of the microwave as compared with that in vacuum. The bottom surface of the wave retardation plate 33 contacts the planar antenna plate 31, and the upper surface thereof contacts the cover member 34 made of a metal material. In the present embodiment, the wave retardation plate 33 has a double structure in which an inner portion and an outer portion are separated from each other.

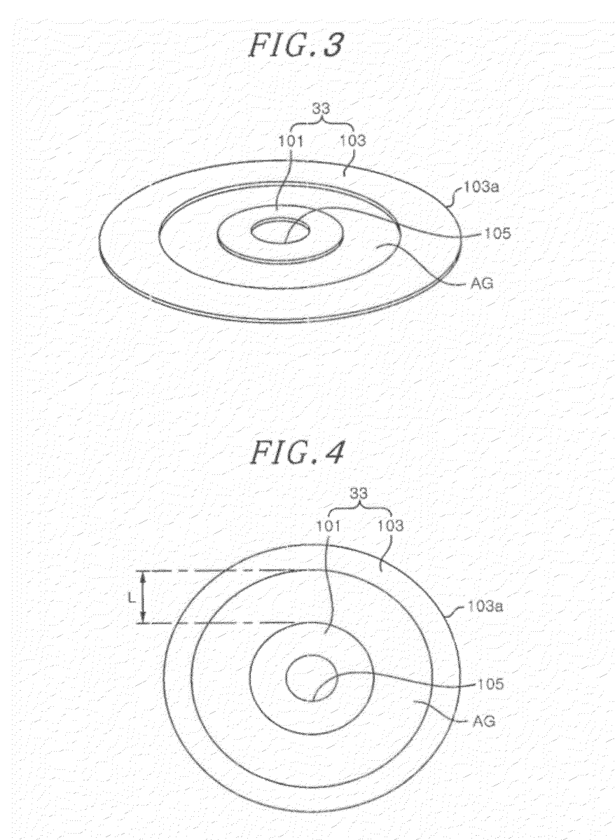

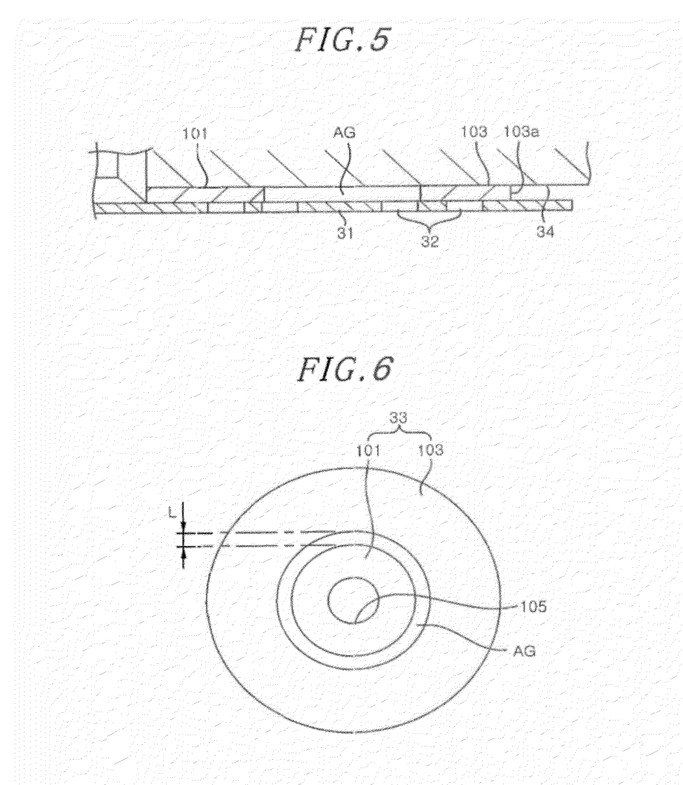

FIG. 3 is an exterior perspective view showing the configuration of the wave retardation plate 33. FIG. 4 is a top view of the wave retardation plate 33. FIG. 5 is a cross sectional view showing principal parts of the wave retardation plate 33 provided above the planar antenna plate 31. The wave retardation plate 33 includes a small-diameter member 101 disposed at an inner side and a large-diameter member 103 surrounding the small-diameter member 101. The small-diameter member 101 and the large-diameter member 103 have a ring-shaped flat plate shape. The small-diameter member 101 and the large-diameter member 103 may be made of materials having the same permittivity or different permittivities. An opening 105 is formed at the central portion of the small-diameter member 101 so as to penetrate therethrough in a thickness direction, so that the small-diameter member 101 can be fixed to an internal conductor 41 (to be described later) passing through the center of the coaxial waveguide 37a. In other words, the small-diameter member 101 is fixed at the opening 105 to the internal conductor 41. The large-diameter member 103 is fixed at a peripheral portion 103a thereof to, e.g., the cover member 34 or the planar antenna plate 31.

The small-diameter member 101 and the large-diameter member 103 are arranged with a gap therebetween. An air layer (air gap (AG)) is formed between the small-diameter member 101 and the large-diameter member 103. In the plasma processing apparatus 100 of the present embodiment, the permittivity of the region between the planar antenna plate 31 and the cover member 34 is controlled by the materials of the small-diameter member 101 and the large-diameter member 103 and the air gap AG, if necessary. Both of the small-diameter member 101 and the large-diameter member 103 are made of a dielectric material having a relative permittivity ε of 1 or more. On the other hand, the air gap AG as an air layer has a relative permittivity ε of about 1. Accordingly, when the upper region adjacent to the planar antenna plate 31 (between the planar antenna plate 31 and the cover member 34) is considered as one entire region, the permittivity of the corresponding region becomes non-uniform on a plane parallel to the upper surface of the planar antenna plate 31 by the configuration of the small-diameter member 101 and the large-diameter member 103. For example, when the small-diameter member 101 and the large-diameter member 103 are made of quartz having a relative permittivity ε of 3.8, the permittivity of the upper region adjacent to the planar antenna plate 31 is changed on the plane parallel to the upper surface of the planar antenna plate 31, e.g., from the internal conductor 41 side toward the diametrically outer side, the relative permittivity being ε=3.8 (the small-diameter member 101), ε=1 (the air gap AG), and ε=3.8 (the large-diameter member 103).

In the present embodiment, the gap between the small-diameter member 101 and the large-diameter member 103 (i.e., the width L of the air gap AG) can be set to any value. For example, as shown in FIG. 6, the width L of the air gap AG can be set to be smaller than that shown in FIG. 4. By changing the width L of the air gap AG, the volume ratio of the air layer to the total volume of the small-diameter member 101 and the large-diameter member 103 can be changed.

Besides, the position of the air gap AG in the diametrical direction can be variably controlled. Even when the width L is the same, the ratio (area ratio and volume ratio) of the small-diameter 101 and the large-diameter member 103 can be controlled by changing the position of the air gap AG. By controlling the arrangement and the ratio of the small-diameter member 101, the large-diameter member 103 and the air gap AG, it is possible to simply change the distribution of the permittivity in the region between the planar antenna plate 31 and the cover member 34.

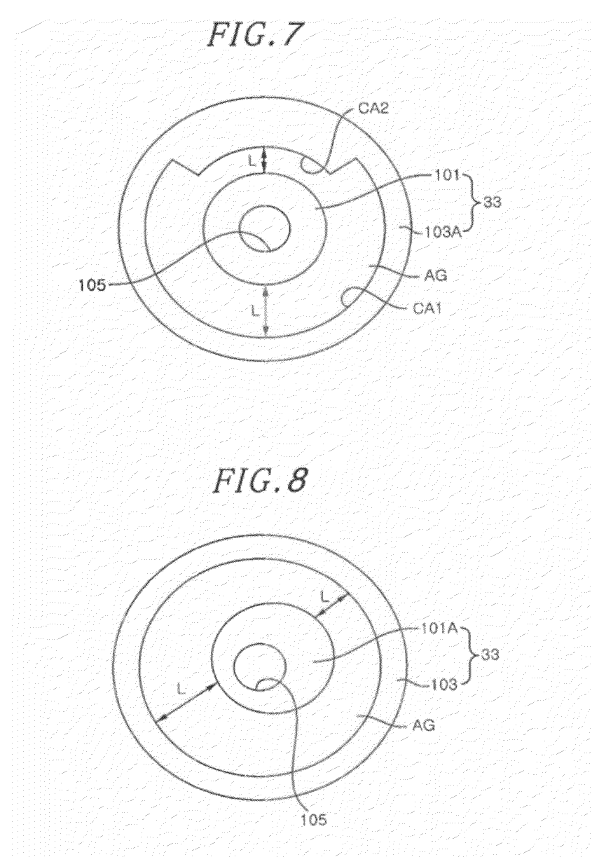

Moreover, he small-diameter member 101 and the large-diameter member 103 of the wave retardation plate 33 may have another shape without being limited to a circular ring shape. For example, FIG. 7 shows an example in which the large-diameter 103 is modified to have an asymmetrical shape. In this example, an inner periphery of a large-diameter member 103A is modified to have a first arc portion CA1 and a second arc portion CA2 having a radius of curvature smaller than that of the first arc portion CA1. Due to this shape, the width L of the air gap AG as the gap between the small-diameter member 101 and the large-diameter member 103A becomes non-uniform and is partially reduced at the portion corresponding to the second arc CA2. Although it is not illustrated, the same configuration can be obtained by modifying the outer peripheral shape of the small-diameter member 101 instead of the inner peripheral shape of the large-diameter member 103.

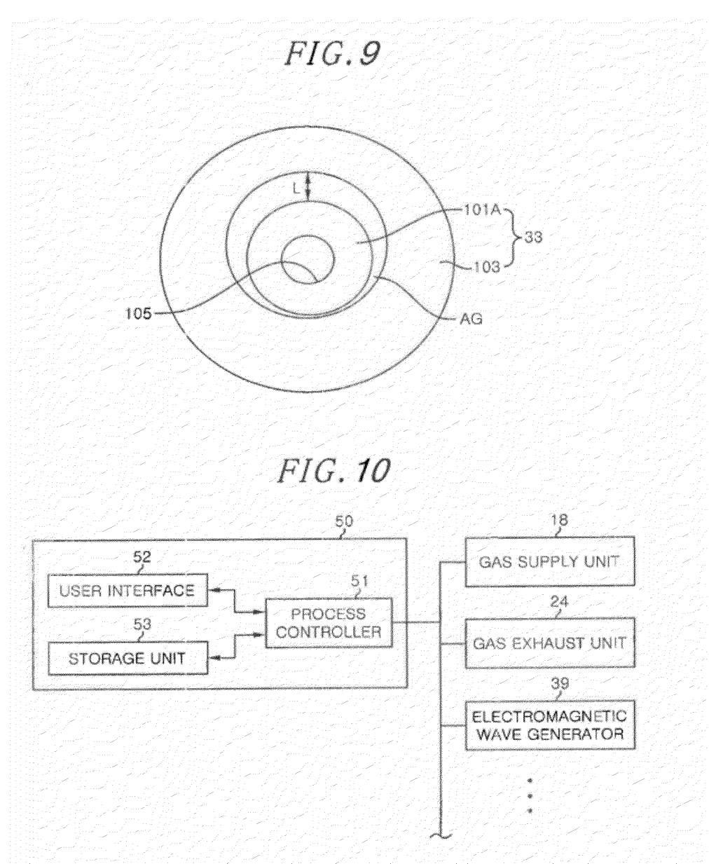

Referring to FIG. 8, for example, the small-diameter member 101A is eccentrically disposed from the center of the large-diameter member 103 (the center of the planar antenna plate 31 or the center of the coaxial waveguide 37a). By eccentrically positioning the small-diameter member 101A such that the outer periphery of the small-diameter member 101A and the inner periphery of the large-diameter member 103 do not form concentric circles, the width L of the air gap AG can be partially decreased by the eccentric width in the eccentric direction and increased by the eccentric width in the opposite direction. Due to the asymmetric shapes or the asymmetric arrangement of the members forming the wave retardation plate 33 shown in FIGS. 7 and 8, the permittivity becomes non-uniform along the diametrical direction and the circumferential direction on the plane parallel to the upper surface of the planar antenna plate 31. Therefore, when the plasma distribution in the processing chamber 1 is not uniform due to local intensity differences, for example, the non-uniformity thereof can be effectively corrected. The same configuration can be obtained by eccentrically positioning the inner periphery of the large-diameter member 103 as shown in FIG. 9.

In the present embodiment, the small-diameter member 101 (101A) and the large-diameter member 103 (103A) can be made of materials having different permittivities. For example, when the small-diameter member 101 and the large-diameter member 103 shown in FIGS. 3 to 5 are made of quartz and alumina Al₂O₃ having a relative permittivity of 8.5, respectively, a relative permittivity in the upper region parallel to the upper surface of the planar antenna plate 31 is changed, e.g., from the internal conductor 41 side toward the diametrically outer side, the relative permittivity being ε=3.8 (the small-diameter member 101), ε=1 (the air gap AG), and ε=8.5 (the large-diameter member 103). As such, by changing the materials of the small-diameter member 101 and the large-diameter member 103, it is possible to simply change the distribution of the permittivity in the region between the planar antenna plate 31 and the cover member 34. When the small-diameter member 101 and the large-diameter member 103 are made of different materials, the non-uniform distribution of the permittivity can be obtained even in a case in which the small-diameter member 101 and the large-diameter member 103 contact with each other without an air gap AG therebetween as long as breakage does not occur due to thermal expansion or the like. In that case, the small-diameter member 101 and the large-diameter member 103 are preferably made of materials having substantially the same thermal expansion coefficient.

In the plasma processing apparatus 100 of the present embodiment, the region above the planar antenna plate 31 can be divided into a plurality of small regions having different permittivities by providing the wave retardation plate 33 divided into a plurality of parts instead of a single-body wave retardation plate. Therefore, the wavelength of the microwave and the distribution of the plasma generated in the processing chamber 1 can be finely controlled compared to the case of using the single-body wave retardation plate. The members forming the wave retardation plate 33 are not limited to the small-diameter member 101 and the large-diameter member 103, and three or more members can be used.

Moreover, it is preferable to set the thickness of the wave retardation plate 33 in consideration of the shortened wavelength caused by the permittivity of the material forming the wave retardation plate 33 and the periodicity of the standing wave in the wave retardation plate 33.

The cover member 34 is provided at an upper portion of the processing chamber 1 to cover the planar antenna plate 31 and the wave retardation plate 33, and has a function of forming a waveguide. The cover member 34 is made of, e.g., a metal material such as aluminum, stainless steel, cupper or the like. The upper surface of the plate 13 and the cover member 34 are sealed by a conductive sealing member 35 such as a spiral shield ring or the like to thereby prevent leakage of the microwave to the outside. Further, a coolant path 34a is formed in the cover member 34. The cover member 34, the wave retardation member 33, the planar antenna 31, and the transmitting plate 28 can be cooled by circulating coolant through the coolant path 34a. Due to the cooling mechanism, the cover member 34, the wave retardation plate 33, the planar antenna plate 31, the transmitting plate 28 and the plate 31 can be prevented from being deformed/damaged by heat of the plasma. The plate 13, the planar antenna plate 31 and the cover member 34 are grounded.

An opening 36 is formed at the center portion of the cover member 34, and a lower end of the waveguide 37 is connected to the opening 36. The electromagnetic wave generator 39 for generating a microwave is connected to the other end of the waveguide 37 via the matching circuit 38. The microwave generated by the electromagnetic wave generator 39 has preferably a frequency of, e.g., 2.45 GHz, and may have a frequency of 800 MHz to 1 GHz (preferably 800 MHz to 915 MHz), 8.35 GHz, 1.98 GHz, or the like.

The waveguide 37 includes a coaxial waveguide 37a having a circular cross section and extending upward from the opening 36 of the cover member 34, and a horizontally-extending rectangular waveguide 37b connected to the upper end portion of the coaxial waveguide 37a via a mode transducer 40. The mode transducer 40 has a function of converting the microwave propagated in a TE mode into a TEM mode through the rectangular waveguide 37b.

An internal conductor 41 extends through the center of the coaxial waveguide 37a. The lower end portion of the internal conductor 41 is fixedly connected to the center of the planar antenna 31. With this structure, the microwaves can be efficiently and uniformly propagated to the planar antenna plate 31 in a radial direction through the coaxial waveguide 37a having the internal conductor 41.

With the above-described configuration of the microwave introducing mechanism 27, the microwave generated by the electromagnetic wave generator 39 is propagated to the planar antenna plate 31 via the waveguide 37, and then is introduced into the processing chamber 1 via the transmitting plate 28.

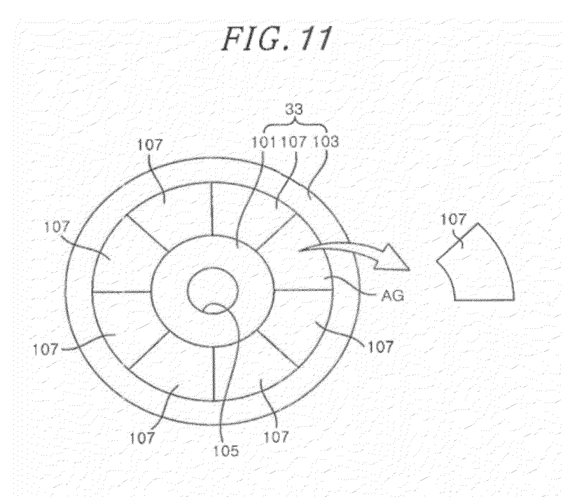

Each component of the plasma processing apparatus 100 is connected to and controlled by a control unit 50. As shown in FIG. 10, the control unit 50 includes a process controller 51 having a CPU, a user interface 52 and a storage unit 53 connected to the process controller 51. The process controller 51 controls the components of the plasma processing apparatus 100 (e.g., the gas supply unit 18, the gas exhaust unit 24, the electromagnetic wave generator 39 and the like) which are related to the processing conditions such as a gas flow rate, a pressure, a microwave output and the like.

The user interface 52 has a keyboard on which a process operator inputs commands to operate the plasma processing apparatus 100, a display for visually displaying the operation status of the plasma processing apparatus 100 and the like. Further, the storage unit 53 stores therein recipes including control programs (software) for implementing various processes executed by the plasma processing apparatus 100 under the control of the process controller 51, processing condition data and the like.

Moreover, the process controller 51 executes a recipe retrieved from the storage unit 53 in response to an instruction from the user interface 52 or the like when necessary, so that a required process is performed by the plasma processing apparatus 100 under the control of the process controller 51. Further, recipes such as the control program, the processing condition data and the like may be stored in a computer-readable storage medium, e.g., a CD-ROM, a hard disk, a flexible disk, a flash memory, a DVD, a Blu-ray disc or the like, or may be transmitted on-line from another device via, e.g., a dedicated line, whenever necessary.

In accordance with the plasma processing apparatus 100 configured as described above, the plasma processing can be performed without inflicting damage to an underlying film or the like. Further, the plasma processing apparatus 100 can realize the processing uniformity since the uniformity of the plasma is excellent.

Hereinafter, an example of the sequence of the plasma processing using the plasma processing apparatus 100 of the present embodiment will be described. Here, the case in which a plasma nitriding process is performed on a surface of a wafer by using a nitrogen-containing gas as a processing gas will be described as an example. First, when an instruction for controlling the plasma processing apparatus 100 to perform a plasma nitriding process is input from the user interface 52, for example, the process controller 51 reads out a recipe stored in the storage unit 53. Then, the control signals are transmitted from the process controller 51 to the end devices of the plasma processing apparatus 100, e.g., the gas supply unit 18, the gas exhaust unit 24, the electromagnetic wave generator 39 and the like, so that the plasma nitriding process can be performed under the conditions corresponding to the recipe.

Thereafter, the gate valve 17 is opened, and the wafer W is loaded into the processing chamber 1 through the loading/unloading port 16 and mounted on the mounting table 2. Next, the processing chamber 1 is depressurized and exhausted, and a nonreactive gas and a nitrogen-containing gas are introduced at predetermined flow rates into the processing chamber 1 from the gas supply unit 18. Further, the pressure in the processing chamber 1 is controlled to a predetermined level by controlling a gas exhaust amount and a gas supply amount.

Then, a microwave is generated by turning on the power of the electromagnetic wave generator 39. Next, the microwave of a predetermined frequency, e.g., 2.45 GHz, is introduced into the waveguide 37 through the matching circuit 38. The microwave introduced into the waveguide 37 sequentially passes through the rectangular waveguide 37b and the coaxial waveguide 37a, and then is supplied to the planar antenna 31. The microwave propagates in the TE mode in the rectangular waveguide 37b. Thereafter, the TE mode of the microwave is converted into the TEM mode by the mode transducer 40, and the microwave in the TEM mode propagates in the coaxial waveguide 37a toward the planar antenna 31. When the microwave propagates through the flat waveguide between the planar antenna plate 31 and the cover member 34, the wavelength of the microwave is shortened by the wave retardation plate 33. In the plasma processing apparatus 100 of the present embodiment, the wave retardation plate 33 has a double structure having a small-diameter member 101 and a large-diameter member 103 with an air gap AG therebetween, if necessary, so that the permittivity of the flat waveguide becomes non-uniform along the outer diametrical direction of the planar antenna plate 31. As a result, the wavelength of the microwave passing through the flat waveguide can be controlled to a desired wavelength.

The microwave having a wavelength shortened by the wave retardation plate 33 is radiated through the microwave irradiation holes 32 formed through the planar antenna plate toward the space above the wafer W in the processing chamber 1 through the transmitting plate 28. In terms of efficiently supplying the microwave, the output of the microwave is preferably set such that a power density per area 1 cm² of the planar antenna plate 31 is within a range between 0.41 W/cm² and 4.19 W/cm². The microwave output can be selected from a range between, e.g., 500 W and 5000 W, such that the power density within the above range can be obtained depending on purposes.

Due to the microwave radiated from the planar antenna into the processing chamber 1 through the transmitting plate 28, an electromagnetic field is generated in the processing chamber 1. When a nitriding process is performed, for example, a nonreactive gas and a nitrogen-containing gas are turned into a plasma. Since the microwave is radiated from a plurality of microwave irradiation holes 32 of the planar antenna plate 31, the plasma is excited by the microwave and turned into a plasma having a high density ranging from about 10^{9/cm}³ to 10^{13/cm}³ and a low electron temperature of about 2 eV in the vicinity of the wafer W. The high-density plasma thus generated causes less plasma damage to the underlying film due to ions. Further, the silicon surface of the wafer W is nitrided by active species in the plasma, e.g., radicals or ions, thereby forming a thin SiN film. In the case of using an oxygen-containing gas instead of a nitrogen-containing gas, the silicon can be oxidized. In the case of using a film forming gas, a film is formed by a plasma CVD method. In the case of using an etching gas, an etching process can be carried out.

When a control signal for instructing completion of the plasma processing is sent from the process controller 51, the power of the electromagnetic wave generator 39 is turned off, and the plasma processing is completed. Next, the supply of the processing gas from the gas supply unit 18 is stopped to exhaust the processing chamber to vacuum. Thereafter, the wafer W is unloaded from the processing chamber 1, and the plasma processing for a single wafer W is completed.

As described above, in the plasma processing apparatus 100 of the present embodiment, the wave retardation plate 33 is made of a dielectric material, and the permittivity of the region between the planar antenna member 31 and the cover member 34 is not uniform along the diametrical direction and/or the circumferential direction on the plane parallel to the upper surface of the planar antenna member 31. Therefore, the plasma distribution in the processing chamber 1 can be controlled by controlling the wavelength of the microwave without exchanging the planar antenna member 31. Accordingly, desired distribution of the plasma can be stably maintained in the processing chamber 1. Even when the processing chamber 1 is scaled up in accordance with the scaling up of the wafer W, the distribution of the plasma generated in the processing chamber 1 can be simply controlled by changing the structure of the wave retardation plate 33.

### Second Embodiment

Hereinafter, a plasma processing apparatus in accordance with a second embodiment of the plasma processing apparatus of the present invention will be described with reference to FIGS. 11 to 13. The plasma processing apparatus of the present embodiment is the same as the plasma processing apparatus 100 (FIG. 1) of the first embodiment except for the configuration of the wave retardation plate 33. Therefore, the redundant description will be omitted, and only the configuration of the wave retardation plate 33 will be described. FIG. 11 is a top view of the wave retardation plate 33 of the second embodiment. The wave retardation plate 33 includes a small-diameter member 101 disposed at an inner side, a large-diameter member 103 surrounding the small-diameter member 101, and a plurality of (eight in FIG. 11) pieces 107 provided between the small-diameter member 101 and the large-diameter member 103. All the pieces 107 are made of a dielectric material. The pieces 107 may be made of a material same as or different from those of the small-diameter member 101 and the large-diameter member 103. Further, each of the pieces 107 may be made of different materials.

In the present embodiment, the pieces 107 are detachably attached to the wave retardation plate 33. One or more pieces 107 can be attached thereto or separated therefrom. FIG. 11 shows a state in which a single piece 107 is separated. When the piece 107 is separated, the corresponding portion becomes an air layer (air gap AG). Therefore, the distribution of the permittivity in the region between the planar antenna plate 31 and the cover member 34 can be simply changed by changing the number of the pieces 107 and the arrangement of the pieces 107. In other words, the permittivity in the corresponding region can become non-uniform in various patterns along the diametrical direction and the circumferential direction on the plane parallel to the upper surface of the planar antenna plate 31.

In FIG. 11, the pieces 107 are in contact with the small-diameter member 101 and/or the large-diameter member 103. However, the pieces 107 may be separated therefrom. When the pieces 107 are in contact with the small-diameter member 101 and/or the large-diameter member 103, the pieces 107 are preferably made of a material having a thermal expansion coefficient substantially the same as that of the small-diameter member 101 and/or the large-diameter member 103. When the pieces 107 are separated from the small-diameter member 101 and/or the large-diameter member 103, an air layer (air gap AG; not shown) is formed at that portion.

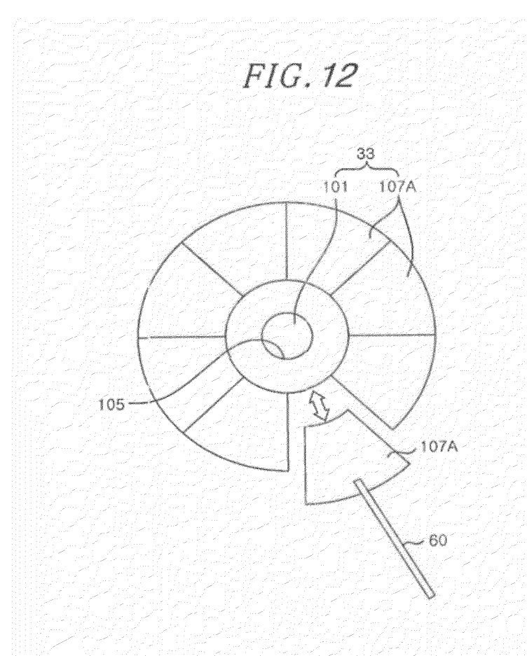

FIG. 12 shows a modification of the wave retardation plate 33 of FIG. 11 in which the small-diameter member 101 and a plurality of (eight in FIG. 12) detachable pieces 107A are combined. In this wave retardation plate 33, the pieces 107A are provided so as to surround the small-diameter member 101. All the pieces 107A are made of a dielectric material. The pieces 107A may be made of a material same as or different from those of the small-diameter member 101. Further, each of the pieces 107A may be made of different materials.

As shown in FIG. 12, the pieces 107A can be detached by using an arm 60. One ore more pieces 107A can be attached or detached by using the arm 60. When the pieces 107A are detached, the corresponding portion becomes an air layer (air gap AG). Therefore, the distribution of the permittivity in the region between the planar antenna plate 31 and the cover member 34 can be simply changed by changing the number of the pieces 107 and the arrangement of the pieces 107. In other words, the permittivity in the corresponding region can become non-uniform in various patterns along the diametrical direction and the circumferential direction on the plane parallel to the upper surface of the planar antenna plate 31.

In FIG. 12, the pieces 107A are in contact with the small-diameter member 101. However, the pieces 107A may be separated therefrom. When the pieces 107A are in contact with the small-diameter member 101, the pieces 107A are preferably made of a material having a thermal expansion coefficient same as that of the small-diameter member 101. When the pieces 107A are separated from the small-diameter member 101, an air layer (air gap AG; not shown) is formed at that portion. Further, the pieces 107A adjacent to each other may be in contact with each other or separated from each other. When the pieces 107A adjacent to each other are in contact with each other, they are preferably made of materials having substantially the same thermal expansion coefficient. When the pieces 107A adjacent to each other are separated from each other, an air layer (air gap AG; not shown) is formed at that portion.

FIG. 13 shows another modification of the present embodiment which includes a base plate 111 and a plurality of flat rectangular pieces 113 detachably attached to the base plate 111. The base plate 111 and the pieces 113 are made of a dielectric material. The pieces 113 may be made of a material same as or different from that of the base plate 111. Moreover, each of the pieces 113 can be made of different materials.

A plurality of cutoff portions 111a is formed at the base plate 111. By inserting the pieces 113 into the cutoff portions 111a or separating the pieces 113 therefrom, it is possible to simply change the distribution of the permittivity in the region between the planar antenna plate 31 and the cover member 34. When the base plate 111 and the pieces 113 are not combined, air layers (air gaps AG) are formed at the cutoff portions 111a, so that the permittivity becomes non-uniform along the diametrical direction and the circumferential direction on the plane parallel to the upper surface of the planar antenna plate 31. When the base plate 111 and the pieces 113 made of the same material are combined by inserting the pieces 113 into the cutoff portions 111a of the base plate 111, the non-uniformity of the permittivity on the plane parallel to the upper surface of the planar antenna plate 31 is solved. When the base plate 111 and the pieces 113 made of different materials are combined, the permittivity is non-uniformly distributed along the diametrical direction and the circumferential direction on the plane parallel to the upper surface of the planar antenna plate 31.

The other configurations and effects of the present embodiment are the same as those of the first embodiment.

### Third Embodiment

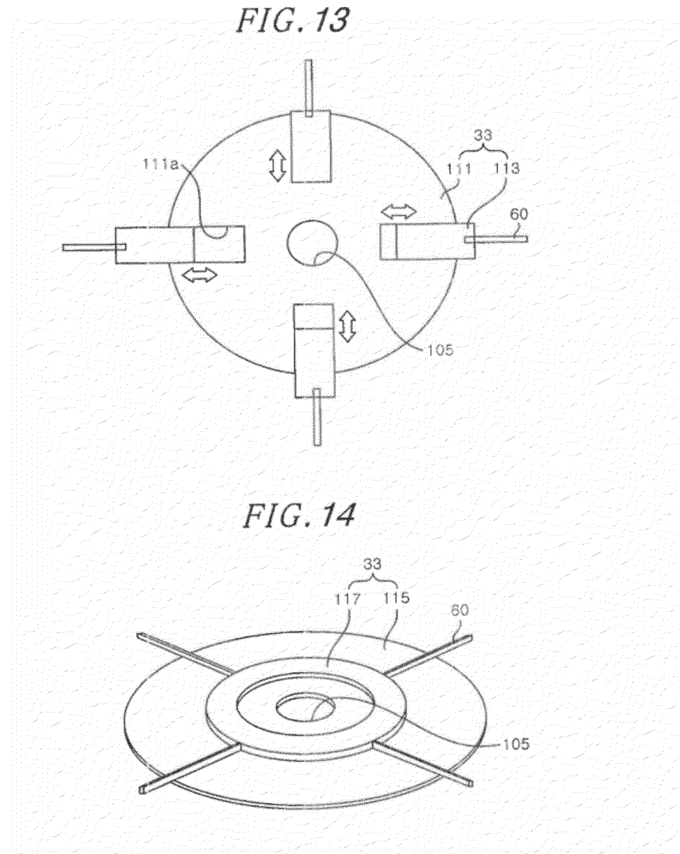

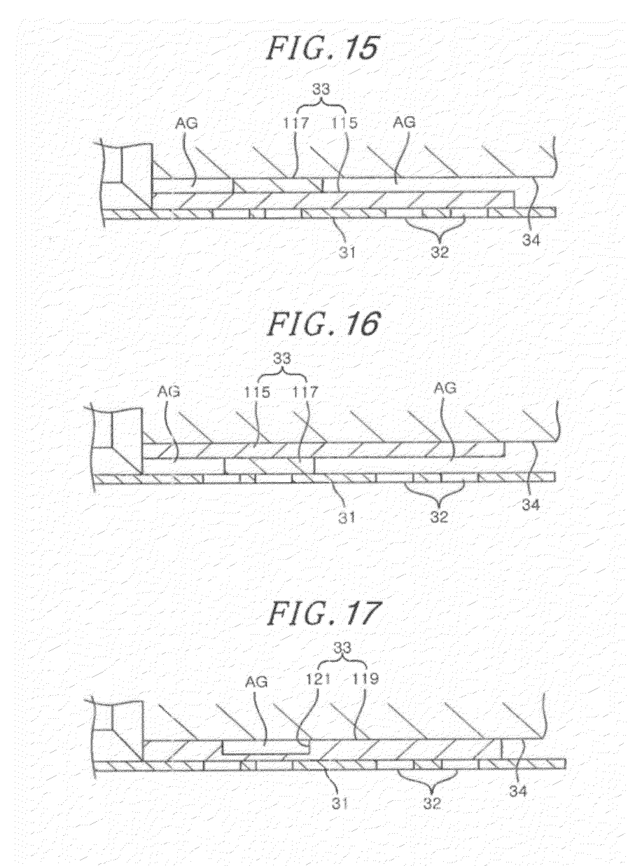

Hereinafter, a plasma processing apparatus in accordance with a third embodiment of the present invention will be described with reference to FIGS. 14 to 16. The plasma processing apparatus of the present embodiment is the same as the plasma processing apparatus 100 (FIG. 1) of the first embodiment except for the configuration of the wave retardation plate 33. Therefore, the redundant description will be omitted, and only the configuration of the wave retardation plate 33 will be described. FIG. 14 is a perspective view showing an exterior configuration of the wave retardation plate 33 used in the third embodiment. FIG. 15 is a cross sectional view of principal parts of the plasma processing apparatus and shows the attachment state of the wave retardation plate 33. The wave retardation plate 33 includes a disc-shaped member 115 having substantially the same area as that of the planar antenna plate 31 and a ring-shaped member 117 provided on the disc-shaped member 115 in an overlapped manner. The ring-shaped member 117 has a smaller area than that of the disc-shaped member 115. Both of the disc-shaped member 115 and the ring-shaped member 117 are made of a dielectric material. The disc-shaped member 115 and the ring-shaped member 117 may be made of the same material or different materials.

In the present embodiment, the distribution of the permittivity in the region between the planar antenna plate 31 and the cover member 34 can be simply changed by combining the ring-shaped member 117 and the disc-shaped member 115. In other words, the region above the disc-shaped member 115 except for the portion where the ring-shaped member 117 having a predetermined permittivity is positioned becomes an air layer (air gap AG), so that the permittivity becomes non-uniform on the plane parallel to the upper surface of the planar antenna plate 31.

Further, the ring-shaped member 117 is movable such that its position on the disc-shaped member 115 can be changed by the arm 60. Since the shape of the air gap AG is changed by changing the arrangement of the ring-shaped member 117, the distribution of the permittivity in the region between the planar antenna plate 31 and the cover member 34 can be simply changed on the plane parallel to the upper surface of the planar antenna plate 31.

Hereinafter, a modification of the wave retardation plate 33 of the present embodiment will be described with reference to FIG. 16. FIG. 16 is a cross sectional view of principal parts of the plasma processing apparatus 100 and shows the attachment state of the wave retardation plate 33. In this modification, the ring-shaped member 117 is in contact with the upper surface of the planar antenna plate 31, and the disc-shaped member 115 is provided thereon in an overlapped manner. In that case, the ring-shaped member 115 is not movable and fixed to, e.g., the internal conductor 41 passing through the center of the coaxial waveguide 73a. In the present embodiment, by inserting the ring-shaped member 117 between the disc-shaped member 115 and the planar antenna plate 31, the permittivity in the region between the planar antenna plate 31 and the cover member 34 can become non-uniform on the plane parallel to the upper surface of the planar antenna plate 31. In other words, the region below the disc-shaped member 115 except for the portion where the ring-shaped member 117 having a predetermined permittivity is positioned becomes an air layer (air gap AG), so that the distribution of the permittivity becomes non-uniform on the plane parallel to the upper surface of the planar antenna plate 31.

The other configurations and effects of the present embodiment are the same as those of the first embodiment.

### Fourth Embodiment

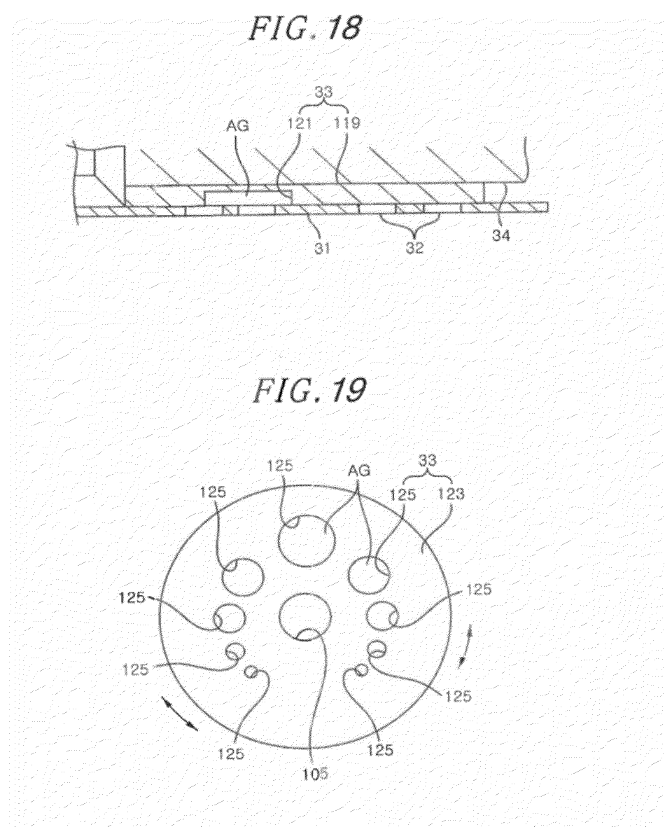

Hereinafter, a plasma processing apparatus in accordance with a fourth embodiment of the present invention will be described with reference to FIGS. 17 and 18. The plasma processing apparatus of the present embodiment is the same as the plasma processing apparatus 100 (FIG. 1) of the first embodiment except for the configuration of the wave retardation plate 33. Thus, the redundant description will be omitted, and only the configuration of the wave retardation plate 33 will be described. FIG. 17 is a cross sectional view of principal parts of the plasma processing apparatus and shows the attachment state of the wave retardation plate 33 used in the fourth embodiment. The wave retardation plate 33 of the present embodiment includes a base plate 119 and a recess, i.e., a groove 121, formed at a portion of the base plate 119. In other words, one or more grooves 121 are formed at the upper surface of the base plate 119 (surface opposite to the surface in contact with the planar antenna plate 31). The positions, shapes, depths, sizes and the like of the grooves 121 are not limited. For example, an annular groove 121 may be formed so as to surround the coaxial waveguide 37a, or a plurality of grooves 121 may be scattered in the base plate 119.

In the present embodiment, by forming the grooves 121 on the upper surface of the base plate 119, the permittivity of the region between the planar antenna plate 31 the cover member 34 can be finely varied on the plane parallel to the upper surface of the planar antenna plate 31. In other words, the portions where the grooves 121 are formed become air layers (air gap AG), and the permittivity difference is produced between the corresponding portions and the base plate 119 having a predetermined permittivity. Thus, the permittivity of the region between the planar antenna plate 31 and the cover member 34 becomes non-uniform on the plane parallel to the upper surface of the planar antenna plate 31. In order to obtain the same effect, the grooves 121 may be formed at a part of the bottom surface of the base plate 119 (surface in contact with the planar antenna plate 31) as shown in FIG. 18. Although it is not illustrated, the grooves 121 may be formed at both of the upper and the lower surface of the base plate 119.

The other configurations and effects of the present embodiment are the same as those of the first embodiment.

### Fifth Embodiment

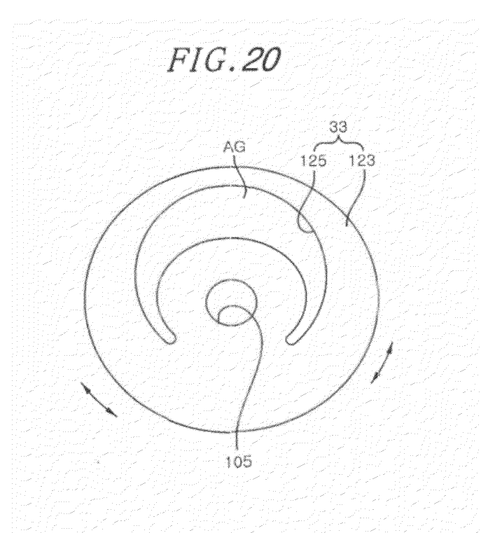

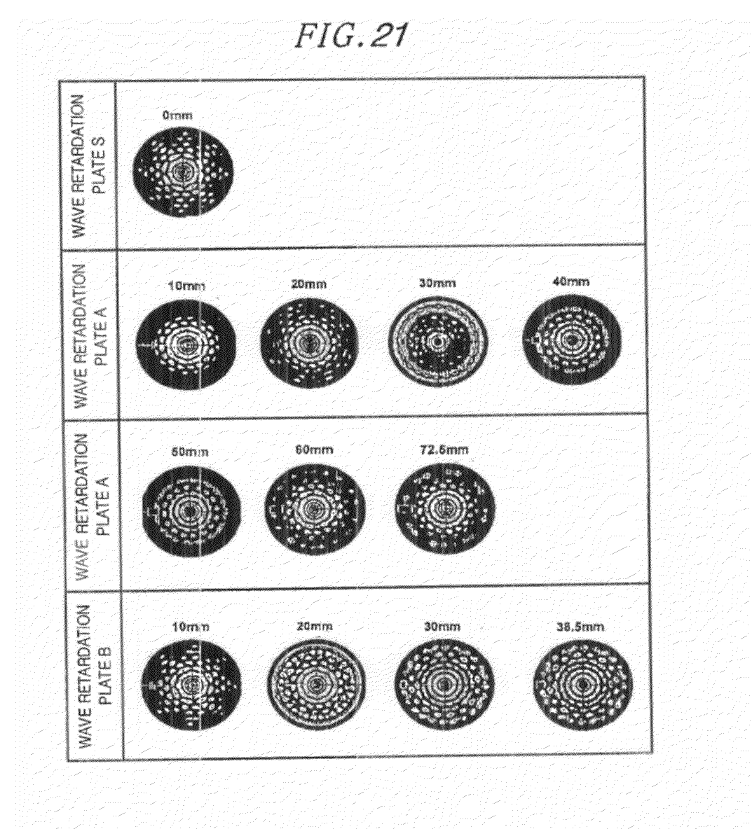

Hereinafter, a plasma processing apparatus in accordance with a fifth embodiment of the present invention will be described with reference to FIGS. 19 and 20. The plasma processing apparatus of the present embodiment is the same as the plasma processing apparatus 100 (FIG. 1) of the first embodiment except for the configuration of the wave retardation plate 33. Therefore, the redundant description will be omitted, and only the configuration of the wave retardation plate 33 will be described. FIGS. 19 and 20 are top views of the wave retardation plate 33 of the present embodiment. The wave retardation plate 33 of the present embodiment includes a single-body base plate 123, and one or more (nine in FIG. 19, one in FIG. 20) through holes 125 penetrating therethrough in a thickness direction thereof. Although the shapes, sizes and positions of the through holes 125 in the base plate 123 are not limited, the through holes 125 are preferably formed in, e.g., a spiral shape, an annular shape, a semi-circular shape, an arc shape, so as to surround the coaxial wave guide 37a.

In the present embodiment, by forming the through holes 125 in the base plate 123, the permittivity of the region between the planar antenna plate 31 and the cover member 34 can be finely varied on the plane parallel to the upper surface of the planar antenna plate 31. In other words, the portions where the through holes 125 are formed become air layers (air gaps AG), so that the permittivity difference is produced between the corresponding portions and the base plate 123 having a predetermined permittivity. Hence, the permittivity becomes non-uniform on the plane parallel to the upper surface of the planar antenna plate 31.

In the wave retardation plate 33 of the present embodiment, the through holes 125 are non-uniformly arranged in the base plate 123. Thus, the distribution of the permittivity in the region between the planar antenna plate 31 and the cover member 34 can be simply changed by rotating the attachment position of the base plate 123 as indicated by arrows in FIGS. 19 and 20 by a random angle, for example.

The other configurations and effects of the present embodiment are the same as those of the first embodiment.

Next, in a plasma processing apparatus having the same configuration as that of the plasma processing apparatus 100 shown in FIG. 1, the effect of the structure of the wave retardation plate 33 on the introduction efficiency of the microwave power into the processing chamber 1 was examined by three-dimensional simulation using a finite element method. As a simulation software, a COMSOL (trademark; by COMSOL Inc.) was used, and the electric field intensity and the distribution thereof below the transmitting plate 28 in the case of using the following three wave retardation plates were obtained. All the wave retardation plates 33 were made of quartz.

Wave retardation plate A (test example): In a wave retardation plate having a double ring structure shown in FIGS. 3 to 5, the diametrical distance from the center to the outer periphery of the small-diameter member 101 was set to about 160 mm, and the width of the air gap AG was set to about 10 mm, 20 mm, 30 mm, 40 mm, 50 mm, 60 mm, and 72.5 mm.

Wave retardation plate B (test example): In a wave retardation plate having a double ring structure shown in FIGS. 3 to 5, the diametrical distance from the center to the outer periphery of the small-diameter member 101 was set to about 195 mm, and the width of the air gap AG was set to about 10 mm, 20 mm, 30 mm, and 38.5 mm.

Wave retardation plate S (comparative example): A single-body disc-shaped member was used.

The result of the simulation test is shown in Table 1 and FIG. 21. In FIG. 21, the electric field intensity distribution below the transmitting plate 28 is indicated in black and white. As approximately illustrated in FIG. 21, a white region represents a high electric field intensity, and a black region represents a low electric field intensity.

TABLE 1

| | Electric field intensity [W] | | |
|---|---|---|---|
| | Wave | Wave | Wave |
| Air gap width | retardation | retardation | retardation |
| (mm) | plate A | plate B | plate S |
| 0 | — | — | 663 |
| 10 | 497 | 669 | — |
| 20 | 547 | 822 | — |
| 30 | 1657 | 806 | — |
| 38.5 | — | 844 | — |
| 40 | 462 | — | — |
| 50 | 449 | — | — |
| 60 | 552 | — | — |
| 72.5 | 569 | — | — |

From the result of the wave retardation plates A and B shown in Table 1, it is seen that the electric field intensity in the processing chamber 1 can be greatly varied by changing the arrangement and the width L of the air gap AG. As shown in FIG. 21, the electric field distribution in the processing chamber 1 can be greatly varied by changing the arrangement and the width L of the air gap AG. For example, in the wave retardation plate A, the electric field distribution tends to be changed depending on the width of the air gap AG. To be specific, when the width L of the air gap AG is 30 mm, the electric field distribution is increased below the peripheral portion of the transmitting plate 28. Further, when the width L is about 40 mm, the electric field distribution is increased below the central portion of the transmitting plate 28. Therefore, the non-uniformity of the electric field distribution can be corrected by increasing the electric field at the portion where the electric field distribution is locally weak by using the configuration (eccentric arrangement) of the wave retardation plate 33 shown in FIGS. 7 and 8, for example.

Next, a plasma nitriding process was performed on a silicon wafer by using the plasma processing apparatus having the same configuration as that of the plasma processing apparatus 100 shown in FIG. 1. As for the wave retardation plate 33, the waver retardation plate having a double ring structure shown in FIGS. 3 to 5 was used. The width of the air gap AG was set to about 30 mm or 40 mm. The processing conditions were set as follows.

[Processing Conditions]

Volume flow rate ratio of N₂ gas/Ar gas: 20%

Flow rate: 200 mL/min(sccm)

Processing pressure: 20 Pa

Microwave output: 1500 W

Temperature of mounting table: 500° C.

Processing time: 90 sec

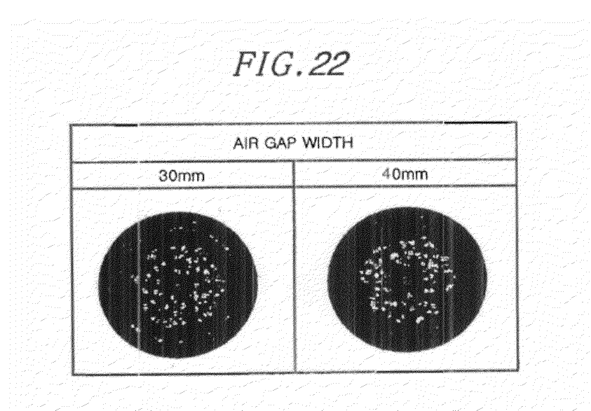

The in-plane wafer uniformity of the plasma nitriding process was examined by measuring the in-plane wafer uniformity of the distribution of the thickness of the silicon nitride film by elipsometer. The result thereof is shown in Table 2. In FIG. 22, the electric field intensity distribution below the transmitting plate 28 is indicated in black and white. As approximately illustrated in FIG. 22, a white region represents a high electric field intensity, and a black region represents a low electric field intensity.

TABLE 2

| | In-plane uniformity of silicon nitride film | | |
|---|---|---|---|
| Air gap width (mm) | Average film thickness (nm) | In-plane film thickness difference (nm) (max- imum film thickness- minimum film thickness) | $\frac{in \text{-} plane film thickness difference}{average film thickness \times 2} \times 100 ( \% )$ |
| 30 | 2.1 | 0.061 | 1.45 |
| 40 | 2.07 | 0.091 | 2.2 |

The above test results show that the in-plane distribution of the film thickness of the silicon nitride film is changed by changing the width L of the air gap AG of the wave retardation plate 33. Therefore, it is clear that the in-plane processing uniformity of the wafer W can be improved by changing the shape and the arrangement of the wave retardation plate 33 of the present invention depending on the processing conditions.

While the embodiments of the present invention have been described, the present invention can be variously modified. For example, the plasma processing apparatus 100 of the present invention is not limited to the plasma nitriding apparatus, and may also be applied to, e.g., a plasma oxidation apparatus, a plasma CVD apparatus, a plasma etching apparatus, a plasma ashing apparatus or the like. Further, in the plasma processing apparatus 100 having the planar antenna plate 31 of the present invention, an object to be processed is not limited to a semiconductor wafer, and may be, e.g., a substrate for a solar cell panel or a flat panel display device such as a liquid display device, an organic EL display device or the like.

What is claimed is:

1. A plasma processing apparatus for performing plasma processing on an object to be processed, comprising:
a vacuum-evacuable processing chamber for accommodating therein an object to be processed;
a planar antenna member for introducing electromagnetic waves generated by an electromagnetic wave generator into the processing chamber;
a waveguide for supplying the electromagnetic waves to the planar antenna member;
a wave retardation plate, provided on the planar antenna member in an overlapped manner, for changing the wavelength of the electromagnetic waves supplied from the waveguide; and
a cover member covering the wave retardation plate and the planar antenna member from above,
wherein the wave retardation plate is made of a dielectric material, and a permittivity of a region between the planar antenna member and the cover member is non-uniform on a plane parallel to an upper surface of the planar antenna member.

2. The plasma processing apparatus of claim 1, wherein the wave retardation plate is formed by combining a plurality of members having a same permittivity or different permittivities.

3. The plasma processing apparatus of claim 2, wherein an air layer is formed between the members of the wave retardation plate.

4. The plasma processing apparatus of claim 2, wherein a part of the members of the wave retardation plate is separable.

5. The plasma processing apparatus of claim 2, wherein an arrangement position of the members of the wave retardation plate is variable.

6. The plasma processing apparatus of claim 1, wherein the wave retardation plate includes: a first member; and a second member larger than the first member, disposed around the first member, wherein an air layer is formed between the first member and the second member.

7. The plasma processing apparatus of claim 1, wherein the wave retardation plate includes: a first member; and a second member larger than the first member, wherein the first member and the second member are arranged in an overlapped manner in a thickness direction thereof.

8. The plasma processing apparatus of claim 7, wherein the first member is in contact with the planar antenna member, and the second member is disposed on the first member in an overlapped manner.

9. The plasma processing apparatus of claim 7, wherein the second member is in contact with the planar antenna member, and the first member is disposed on the second member in an overlapped manner.

10. The plasma processing apparatus of claim 1, wherein the wave retardation plate is formed in a flat plate shape and has a plurality of recesses formed in a thickness direction thereof, and an air layer is formed in each of the recesses.

11. The plasma processing apparatus of claim 1, wherein the wave retardation plate is formed in a flat plate shape having a plurality of through holes formed in a thickness direction thereof, and an air layer is formed in each of the through holes.

12. A wave retardation plate, provided on a planar antenna member of a plasma processing apparatus in an overlapped manner, for changing a wavelength of an electromagnetic wave supplied from a waveguide, wherein
the wave retardation plate is made of a dielectric material, and a permittivity of a region between the planar antenna member and a cover member covering the planar antenna member from above is non-uniform on a plane parallel to an upper surface of the planar antenna member.
